(19) United States
(12) Patent Application Publication
(10) Pub. No.: US 2011/0106468 A1
(43) Pub. Date: May 5, 2011

(54) LOCATION-ADJUSTING INSPECTING APPARATUS AND METHOD FOR A SOLAR BATTERY PANEL INSPECTING SYSTEM

(76) Inventors: Cheng-Kai Chen, Taoyuan County (TW); Lung-Chang Ho, Taoyuan County (TW); Che-Min Lin, Taoyuan County (TW); Yin-Yuan Chang, Taoyuan County (TW)

(21) Appl. No.: 12/612,047

(22) Filed: Nov. 4, 2009

(51) Int. Cl. G01R 31/02; G06F 19/00

(52) U.S. Cl. 702/58; 324/750.19; 324/761.01

(57) ABSTRACT

The present invention relates to a location-adjusting inspecting apparatus and method for a solar battery panel inspecting system. The inspecting apparatus includes an image-fetching device and a set of rotatable probe devices. A transport platen of the inspecting system transports a solar battery panel to an inspecting region. The image-fetching device fetches an image of electrode lines on the battery panel, and calculates an offset data by comparing the fetched image with a correct data representing the position and angle of electrode lines. Finally, the probe devices are controlled to generate a corrective rotation based on the calculated offset data. In this way, when pressing the solar battery panel, the probes of the probe devices can be aligned with and contact the electrode lines of the solar battery panel correctly, thereby increasing the accuracy in the inspection of the solar battery panel.

### BACKGROUND OF THE INVENTION

1. Field of the Invention

The present invention relates to a solar battery panel, and in particular to an inspecting apparatus and method for a solar battery panel.

2. Description of Prior Art

Generating electricity by solar energy conforms to the requirements for environmental protection because it will not generate any greenhouse gas such as carbon dioxide during its generation of electricity. Thus, since the greenhouse effect and the environmental protection are important issues nowadays, the solar energy has become one of the natural energy sources that can be developed in the future. Therefore, solar battery panels have already been used in daily life, whereby the solar energy can be transformed into electricity.

The value of a solar battery panel depends on the photoelectric conversion efficiency thereof. Thus, each of the solar battery panels has to be inspected in terms of the conversion efficiency. During the inspection, if the photoelectric conversion efficiency of the solar battery panel is lower than a standard value or abnormal, this solar battery panel will be considered as a bad product.

Please refer to FIGS. 1A and 1B. The conversion efficiency of the most common solar battery panel (referred to as “battery panel” hereinafter) is inspected by an inspecting apparatus 10 of an automatic inspecting system. A transport platen 11 supports and rotates to transport a battery panel 2 to an inspecting region. Then, at least one set of probe rows or probe cards 12 press vertically to contact a plurality of electrodes lines on the surface of the battery panel 2. In this way, after the battery panel 2 generates electricity, the voltage and current outputted by the battery panel 2 are calculated to determine the efficiency of the battery panel 2. A solar simulator (not shown) of the inspecting apparatus 10 emits simulative sunlight with high intensity to illuminate vertically a surface of the battery panel 2, whereby the battery panel 2 can generate electricity.

However, the solar battery panel 2 is constituted primarily of a plurality of silicon chips, which are light, thin and fragile. On the other hand, during the transportation, the battery panel 2 may deviate from its original position due to the transporting speed, the friction force resulted from the contact with the transport platen 11 or other possible factors. As a result, after the battery panel 2 is transported to the inspecting region, the probe cards cannot contact the electrode lines of the solar battery panel 2 correctly when pressing. Thus, the measured voltage and current will not be consistent with the actual output values, so that the battery panel 2 may be determined by the inspecting apparatus 10 erroneously as a bad product.

Therefore, in view of the above-mentioned problems, an inspecting apparatus 10′ shown in FIGS. 2A and 2B is proposed. As shown in these figures, both sides of the inspecting region are provided with a contact-type adjusting device 13 respectively for adjusting the angle of the battery panel 2 positioned in the inspecting region. When the battery panel 2 is transported to the inspecting region by the transport platen 11, the adjusting devices 13 on both sides of the inspecting region extend inwards to contact the edges of the battery panel 2. By this contact adjustment, the position and angle of the battery panel 2 in the inspecting region can be corrected. Thus, the position of the electrode lines on the battery panel 2 can be aligned correctly with the probe cards 12 located above and under the battery panel 2. When the probe cards 12 press the battery panel 2 in the vertical direction, they can contact the electrode lines of the battery panel 2 accurately.

However, the above-mentioned solar battery panel 2 is very fragile. Thus, unnecessary contact has to be avoided during the inspection. When the probe cards 12 press vertically to contact the electrode lines of the battery panel 2, the adjusting device 13 also touches the edges of the battery panel 2 to make the battery panel 2 unmovable. As a result, the edges of the battery panel 2 may suffer damage. On the other hand, the position and angle of the battery panel 2 can be adjusted by the contact-type adjusting device 13 only in such a manner that the battery panel 2 is aligned with the probe cards 12 of the inspecting apparatus 10′. Thus, as for the battery panels with some minor defects during the printing process, the inspecting apparatus 10′ may generate a wrong determination, the reasons of which will be described as follows.

Please refer to FIG. 3A. The electrode lines 21 of a common solar battery panel 2 are printed on the surface of the battery panel 2 by means of a screen printing process. In general, the upper surface of the battery panel 2 is n electrode, while the lower surface is p electrode. When the battery panel 2 generates electricity due to the illumination of sunlight, the electrode lines 21 are caused to be electrically conductive to output voltage and current. However, during the screen printing process, there may be minor errors in the geometries of the electrode lines 21 and battery panel 2, such as another solar battery panel 2′ shown in FIG. 3B. In comparison with the battery panel 2′ shown in FIG. 3B with a normal battery panel 2, it is found that the electrode lines 21′ on the battery panel 2′ are slightly oblique. Thus, even using the contact-type adjusting device 13 of the inspecting apparatus 10′, the electrode lines 21′ of the battery panel 2′ still cannot be aligned correctly with the probe cards 12 located above and under the battery panel. As a result, the measured efficiency will be lower than the actual value. Although there are some errors in the electrode lines 21′ of the battery panel 2′, they still have the same efficiency as that of a normal battery panel 2. Thus, such a battery panel 2′ should not be considered as a bad product. In view of this, if such an erroneous determination cannot be avoided, a lot of battery panels 2′ will be thrown away, which causes a great loss to the manufacturers.

### SUMMARY OF THE INVENTION

The present invention is to provide a location-adjusting inspecting apparatus and method for a solar battery panel inspecting system, whereby probe devices can be controlled to generate a corrective rotation to correspond to the position and angle of the electrode lines on the solar battery panel correctly based on the image of the electrode lines of the solar battery panel. Thus, the probe rows of the probe devices can press vertically to contact the electrode lines of the battery panel completely, thereby increasing the accuracy in the inspection.

The present invention provides a location-adjusting inspecting apparatus comprising an image-fetching device and a set of rotatable probe devices. A transport platen of a solar battery panel inspecting system transports a solar battery panel to an inspecting region. The image-fetching device of the location-adjusting inspecting apparatus fetches the image of electrode lines on the battery panel, and calculates an offset data by comparing the fetched image with a correct data representing the position and angle of electrode lines. Finally, the probe devices generate a corrective rotation based on the calculated offset data.

In comparison with prior art, the present invention has advantageous features as follows. Since the positioning of the solar battery panel is executed in a non-contact manner, the problem that the edges of the solar battery panel may suffer damage due to the direct contact when correcting the position of the battery panel can be avoided. Further, as for the solar battery panel printed with oblique electrode lines, the probe devices can generate a corrective rotation to correspond to the position and angle of the electrode lines before the probe devices press the battery panel. Thus, the conversion efficiency may not be measured erroneously due to the oblique electrode lines, and such a battery panel with oblique electrode lines may not be considered as a bad product.

### BRIEF DESCRIPTION OF DRAWING

FIG. 1A is a top view showing the structure of the inspecting apparatus of prior art;

FIG. 1B is a side view showing the structure of the inspecting apparatus of prior art;

FIG. 2A is a top view showing the structure of the inspecting apparatus having a contact-type adjusting device;

FIG. 2B is a side view showing the structure of the inspecting apparatus having a contact-type adjusting device;

FIG. 3A is a schematic view showing an embodiment of the solar battery panel;

FIG. 3B is a schematic view showing another embodiment of the solar battery panel;

FIG. 4A is a top view showing the structure of a preferred embodiment of the present invention;

FIG. 4B is a side view showing the structure of a preferred embodiment of the present invention;

FIG. 5 is a flow chart of a preferred embodiment of the present invention;

FIG. 6 is a schematic view showing the first action of the inspecting apparatus of the present invention;

FIG. 7 is a schematic view showing the second action of the inspecting apparatus of the present invention;

FIG. 8 is a schematic view showing the third action of the inspecting apparatus of the present invention;

FIG. 9 is a schematic view showing the fourth action of the inspecting apparatus of the present invention;

FIG. 10 is a schematic view showing the fifth action of the inspecting apparatus of the present invention;

FIG. 11 is a schematic view showing the sixth action of the inspecting apparatus of the present invention; and

FIG. 12 is a schematic view showing the seventh action of the inspecting apparatus of the present invention.

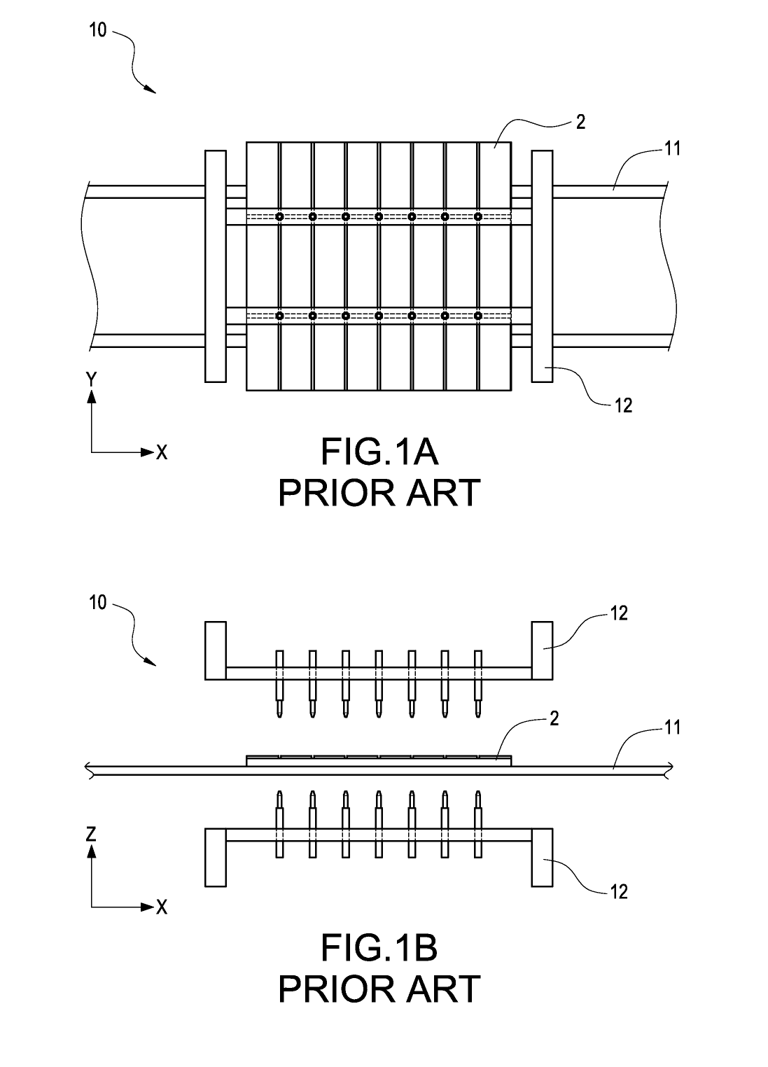

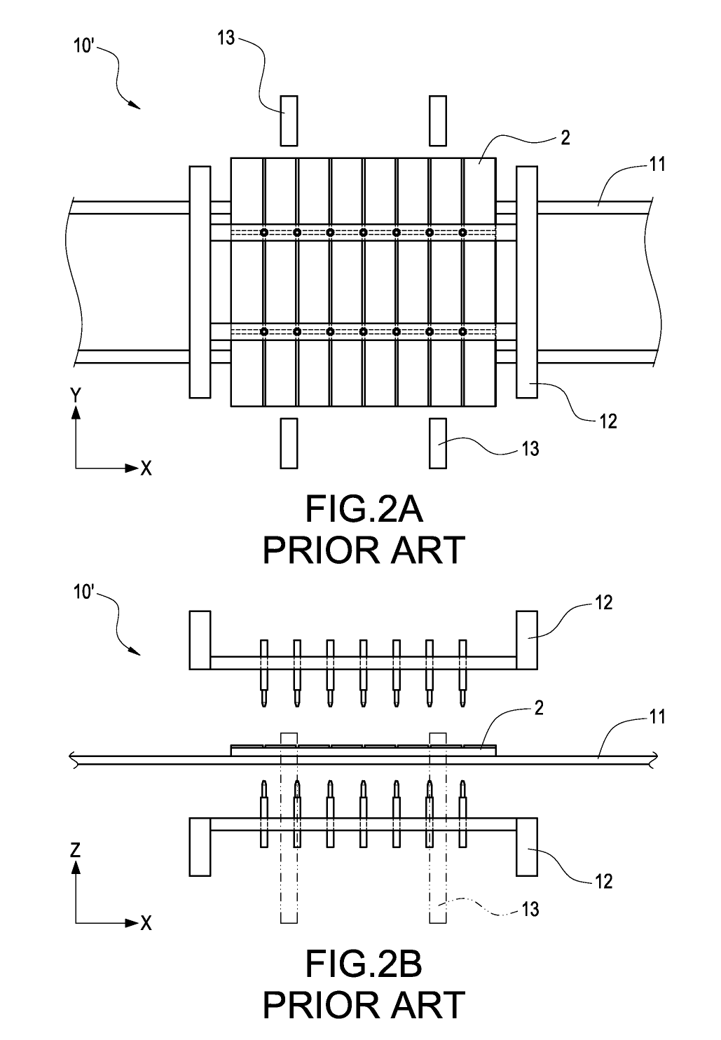

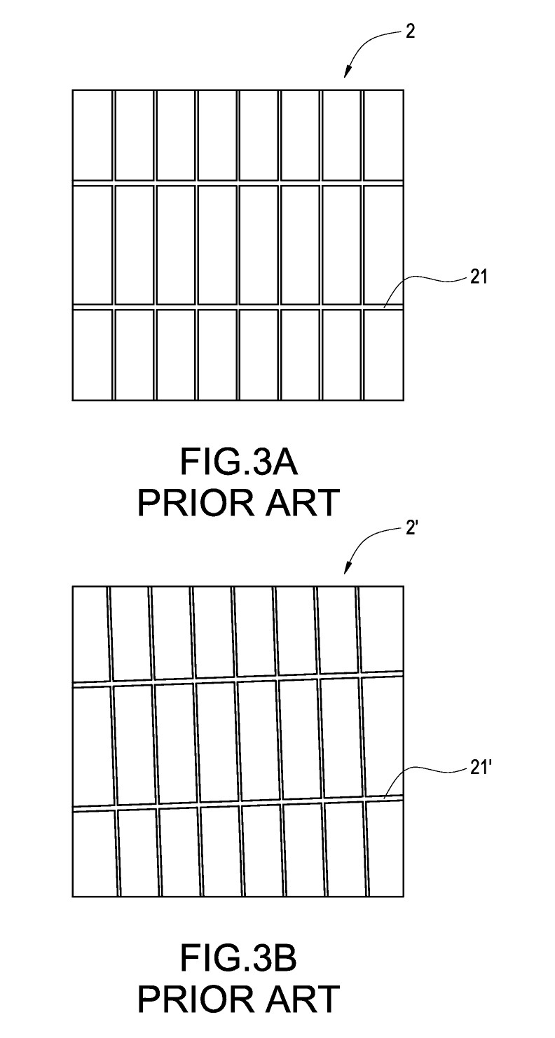

### DETAILED DESCRIPTION OF THE INVENTION

A preferred embodiment of the present invention will be described with reference to the drawings.

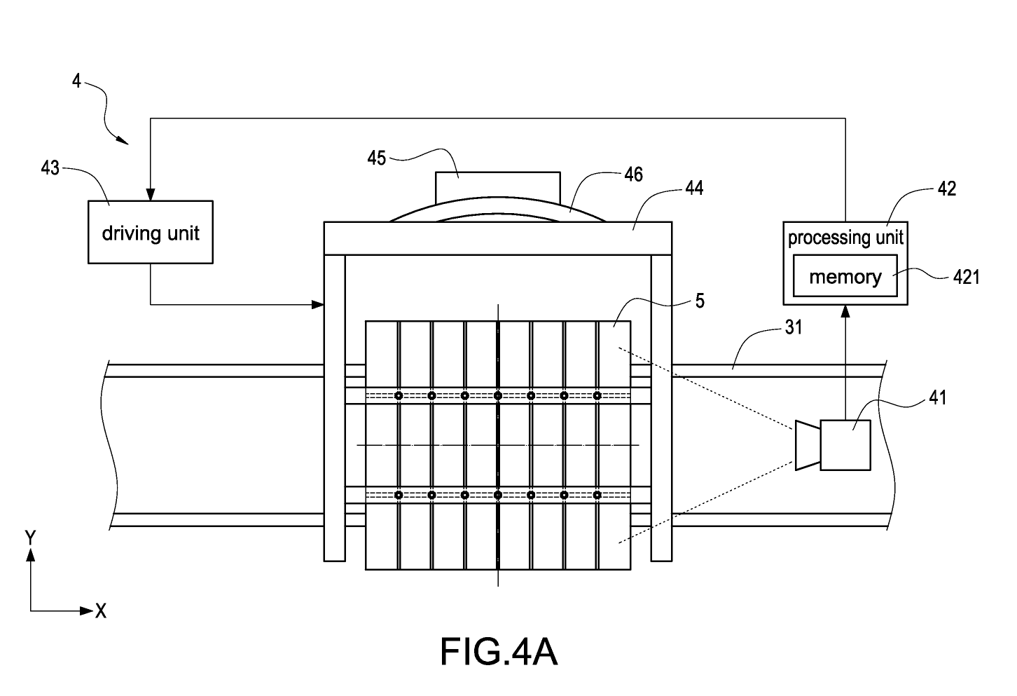

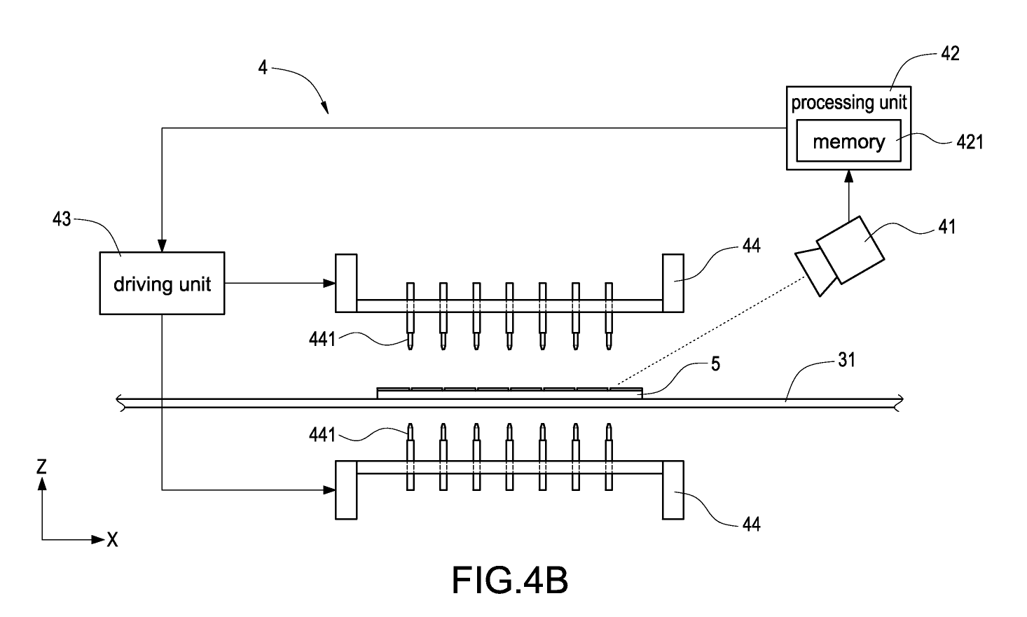

Please refer to FIGS. 4A and 4B. FIG. 4A and FIG. 4B are a top view and a side view showing the inspecting apparatus of a preferred embodiment of the present invention respectively. The inspecting apparatus 4 of the present invention is provided in an inspecting region of a solar battery panel inspecting system (not shown). A transport platen 31 of the inspecting system transports a solar battery panel 5 (referred to as “battery panel 5” hereinafter) continuously in a horizontal direction and stops intermittently to make the battery panel 5 stay in the inspecting apparatus 4 for inspection. The inspecting apparatus 4 includes an image-fetching device 41, a processing unit 42, a driving unit 43 and a set of probe devices 44 rotatable in Y-axis (horizontal) direction and Z-axis (vertical) direction. The image-fetching device 41 fetches an image of the electrode lines on the battery panel 5 and transmits the fetched image to the processing unit 42 electrically connected to the image-fetching device 41. The processing unit 42 compares the fetched image with a correct data so as to generate an offset data, where the correct data is stored in a memory 421 representing the position and angle of the electrode lines. Since the battery panel 5 is transported in the horizontal direction by the transport platen 31, a sunlight-receiving surface of the battery panel 5 has to receive the vertical illumination of simulated sunlight emitted by a solar simulator (not shown). As a result, the image-fetching device 41 cannot be provided in the illumination path of the solar simulator and the transporting path of the transport platen 31. As shown in FIG. 4B, the image-fetching device 41 can be provided at one side of the inspecting region to be oriented toward the inspecting region along the transporting path of the transport platen 31. In this figure, the image-fetching device 41 is provided at right side of the inspecting region to be oriented toward the inspecting area in a direction reverse to the transporting path of the transport platen 31. However, the arrangement of the image-fetching device 41 is not limited thereto. Further, in this figure, there is only one image-fetching device 41 for clarity. However, more than one image-fetching device 41 can be provided to fetch images with better precision, and thus the number of the image-fetching device is not limited thereto.

The probe devices 44 are provided above and under the solar battery panel 5 staying in the inspecting apparatus 4 respectively. Each of the probe devices 44 is formed into an inverted-U shape with the center of the inverted-U shape being connected to a base 45 of the inspecting apparatus 4. A ball valve 46 is pivotally connected to the top and bottom of the base 45. With the above arrangement, the set of probe devices 44 can be obtained. After the comparison executed by the processing unit 42 is completed, the offset data will be transmitted to the driving unit 43 if the correction is necessary. The driving unit 43 is electrically connected to the processing unit 42 and the probe devices 44, and it drives the probe devices 44 to generate a corrective rotation based on the received offset data. In this way, a plurality of probes 441 of the probe devices 44 can be aligned with the position and angle of the electrode lines of the battery panel 5. Further, the image-fetching device 41 may be provided at one side of the probe device 44 above the solar battery panel and fetches images toward the inspecting region along the transporting path of the transport platen 31.

After the probe devices 44 press the battery panel 5 in the vertical direction (along the Z-axis direction in FIG. 4B), the probes 441 contact the electrode lines printed on the upper and lower surfaces of the battery panel 5, thereby generating electrical conduction to measure the voltage and current efficiency of the battery panel 5. If the electrode lines are printed on the battery panel 5 obliquely, the driving unit 43 drives the probe devices 55 to generate a corrective rotation to correspond to the position and angle based on the offset data. More specifically, the probe devices 44 move in the Y-axis direction of FIG. 4A to rotate an angle θ corresponding to the offset data, and then they press the battery panel 5 in the Z-axis direction. In this way, the probes 441 can contact the electrode lines on the battery panel 5 accurately when the probe devices 44 press the battery panel 5. Even though the electrode lines are printed obliquely, the data can be measured accurately by the probe devices 44. The corrective rotation and pressing of the probe devices 44 are driven by the driving unit 43. The driving unit 43 is activated by means of a motor screw, a motor cam or cylinder. The number of the probe devices 44 and the probes 441 is determined based on the number of the electrode lines on the battery panel 5, so that it is not limited to any specific number.

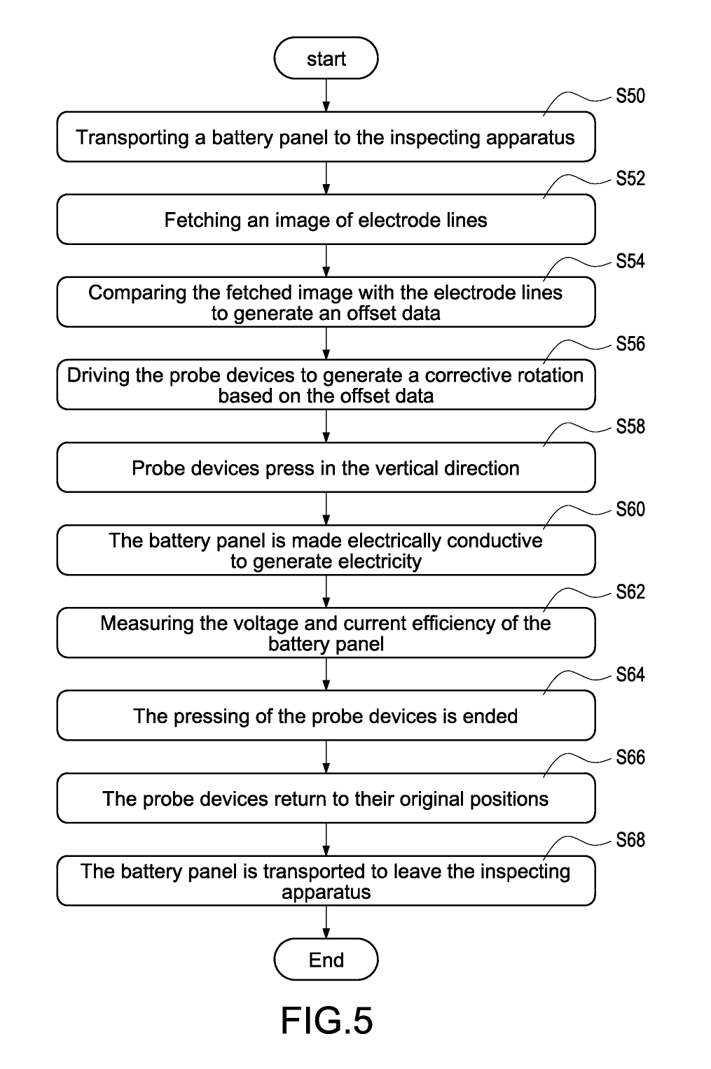

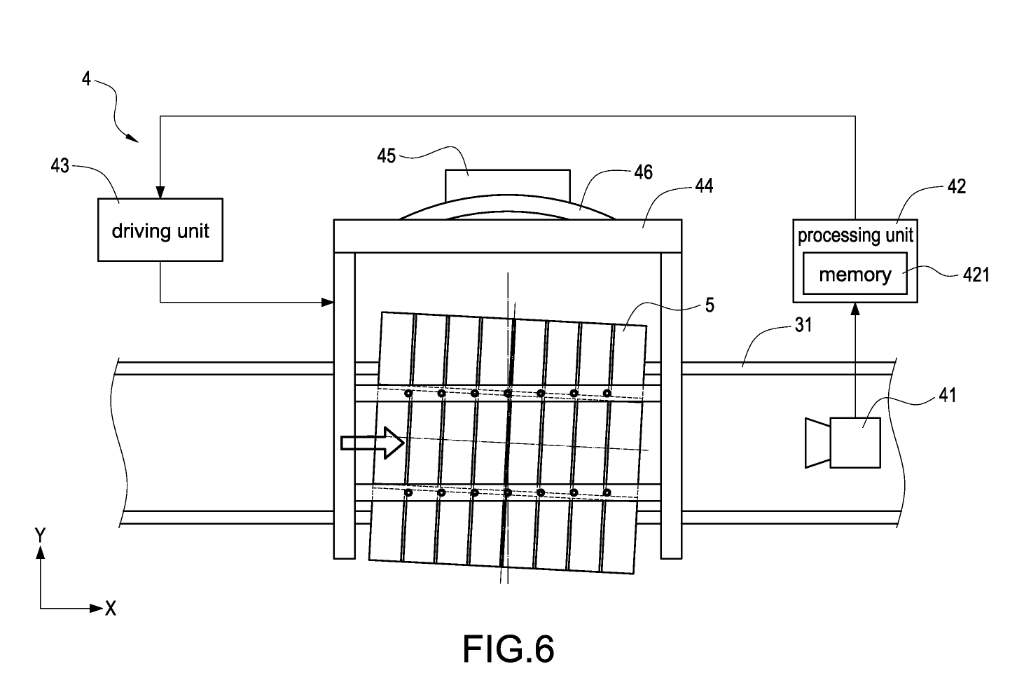

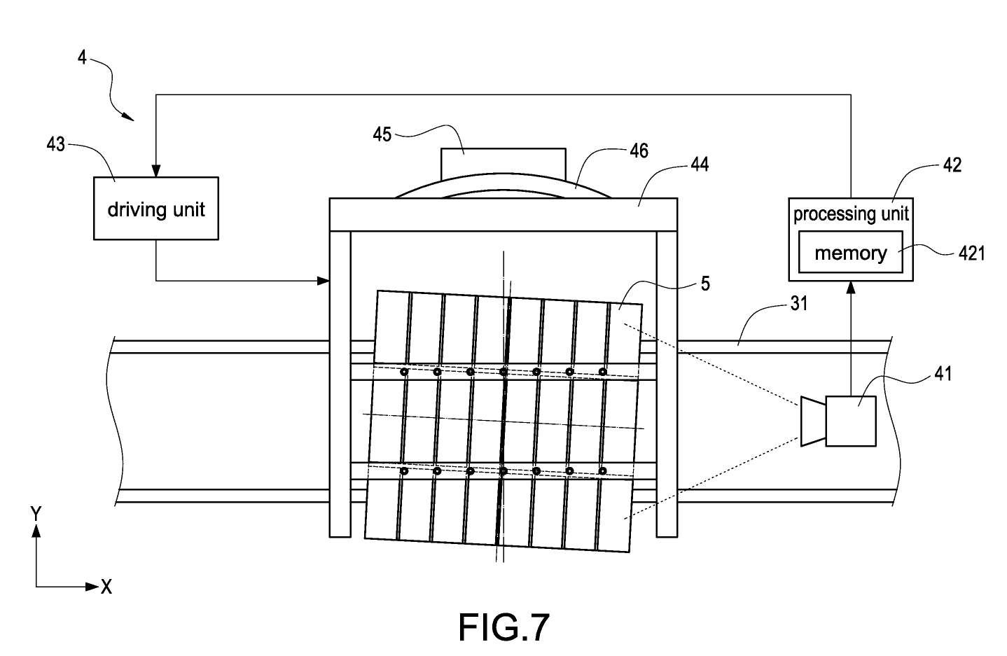

Next, please refer to FIG. 5, which is a flow chart showing a preferred embodiment of the present invention. Please also refer to FIGS. 6 to 12 each showing an action performed in the present invention. First, as shown in FIG. 6, the transport platen 31 transports the battery panel 5 to the inspecting region, that is to transport the battery panel to the inspecting apparatus 4 (step S50). Then, as shown in FIG. 7, the image-fetching device 41 of the inspecting apparatus 4 fetches the image of the electrode lines on the battery panel 5 (step S52). After the image-fetching device 41 of the inspecting apparatus 4 fetches the image of the electrode lines of the battery panel 5, the fetched image is transmitted to the processing unit 42 and then is compared with a data of electrode lines stored in the memory 421, thereby generating an offset data based on the comparison result (step S54). If more than one image-fetching device 41 are provided in the inspecting apparatus 4, the images of the electrode lines can be fetched in different directions and compared with the correct data for several times. In this way, the angle of the electrode lines can be determined more accurately.

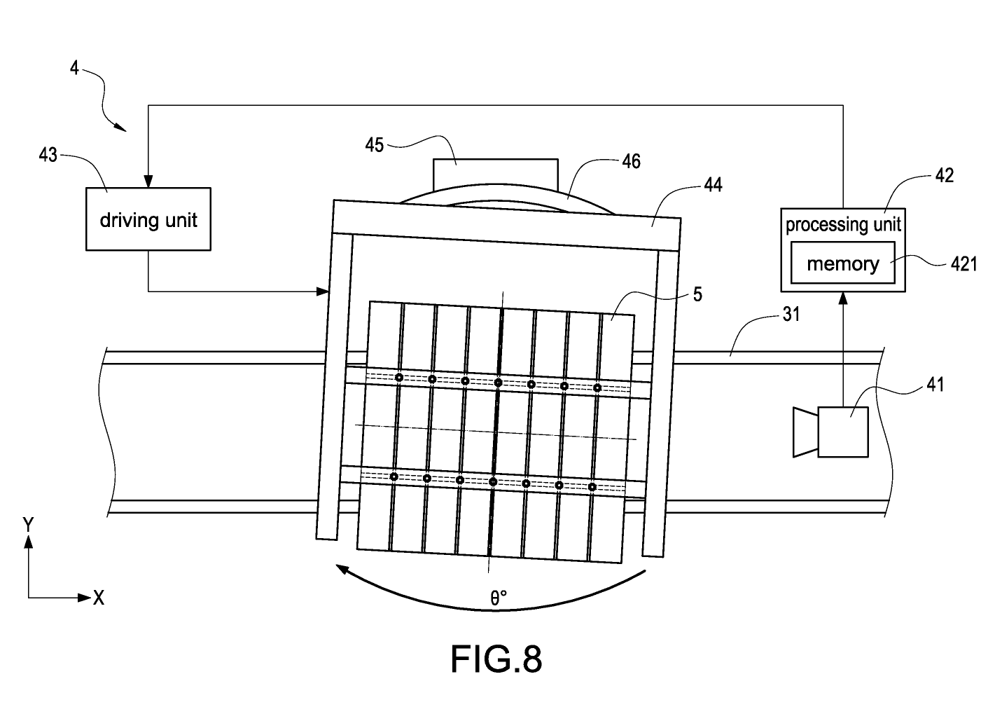

Next, as shown in FIG. 8, the processing unit 42 transmits the offset data to the driving unit 43, so that the driving unit 43 drives the probe devices 44 to generate a corrective rotation to correspond to the position and angle of the probe device 44 (step S56). The probe devices 44 move in the horizontal direction and rotate an angle θ to correspond to of the offset data. After the corrective rotation is executed, the probes 441 of the probe devices 44 can be aligned with the position and angle of the electrode lines on the battery panel 5. For example, if the image fetched by the image-fetching device 41 of the inspecting apparatus 4 is inclined 10 degrees in the clockwise direction by comparing with the correct data of the electrode lines of the battery panel 5. That is to say, the driving unit 43 drives the probe devices 44 to rotate clockwise 10 degrees in the horizontal direction (θ=10°), thereby corresponding to the electrode lines of the battery panel 5. In this situation, the position and angle of the battery panel 5 arranged on the transport platen 31 may be affected by an external force. Or, the electrode lines may be printed on the battery panel 5 obliquely. In either case, the apparatus and method of the present invention can correct the offset. Thus, the probes 441 of the probe devices 44 can be aligned with the electrode lines of the battery panel 5 correctly, so that errors may not occur during the inspection.

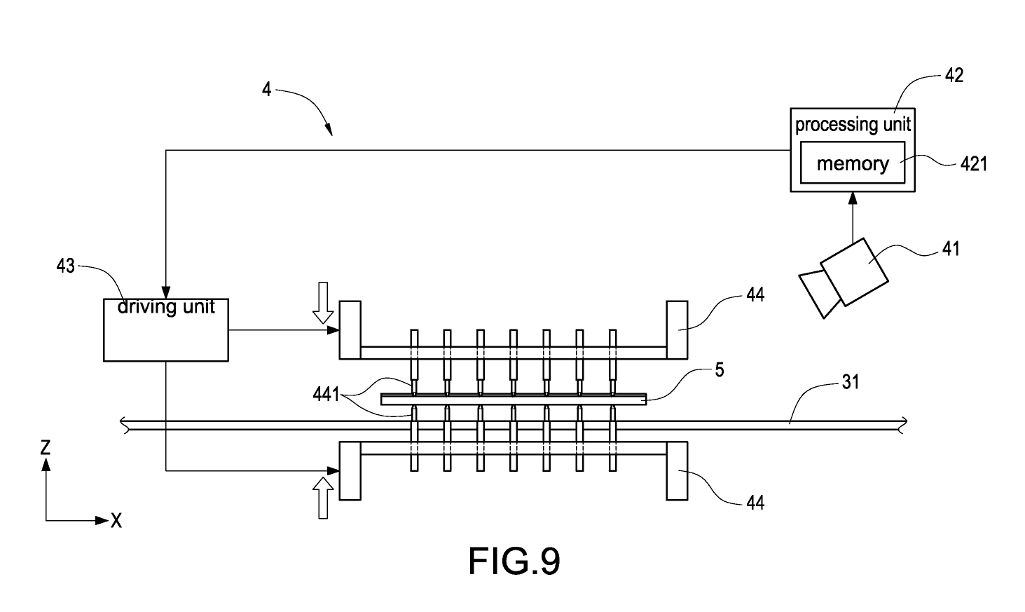

After the step S56 is executed, the probes 441 of the probe devices 44 are aligned with the electrode lines of the battery panel 5 correctly. Next, as shown in FIG. 9, the probe devices 43 are driven by the driving unit 43 to press in the vertical direction, so that the probes 441 can contact the electrode lines of the battery panel 5 (step S58). It should be noted that both of the probe devices 44 can press in a synchronous or non-synchronous manner. For example, the probe device 44 above the solar battery panel first presses downwards to make the probes 441 to contact the electrode lines on the upper surface of the battery panel 5. Then, the probe device 44 under the probe device 4 presses upwards to make the probes 441 to contact the electrode lines on the lower surface of the battery panel 5, or vice versa. Alternatively, the probe devices 44 above and under the inspecting apparatus 4 press simultaneously in the vertical direction. However, the present invention is not limited thereto.

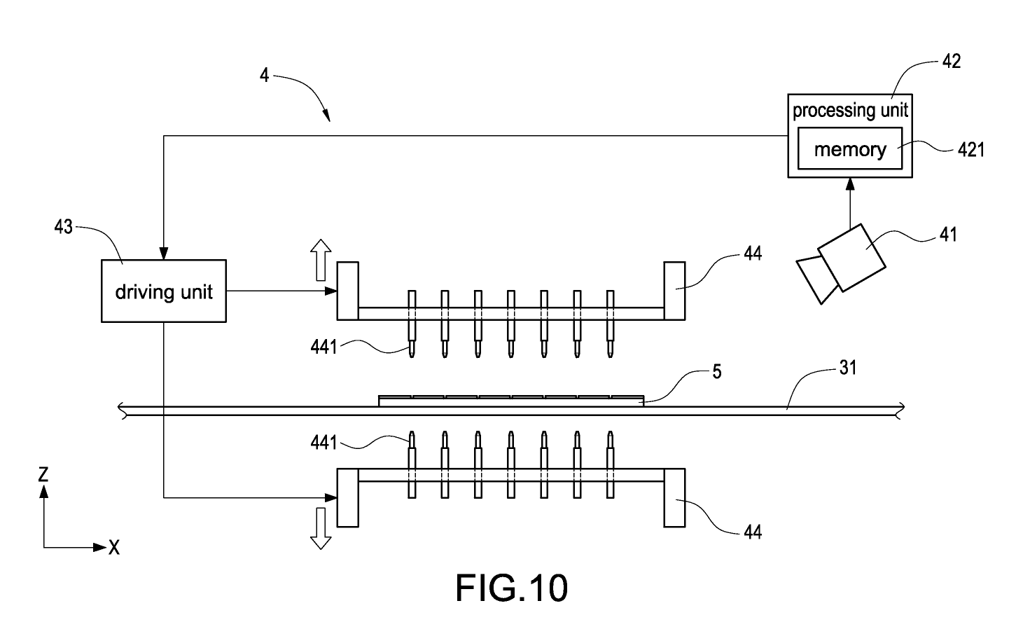

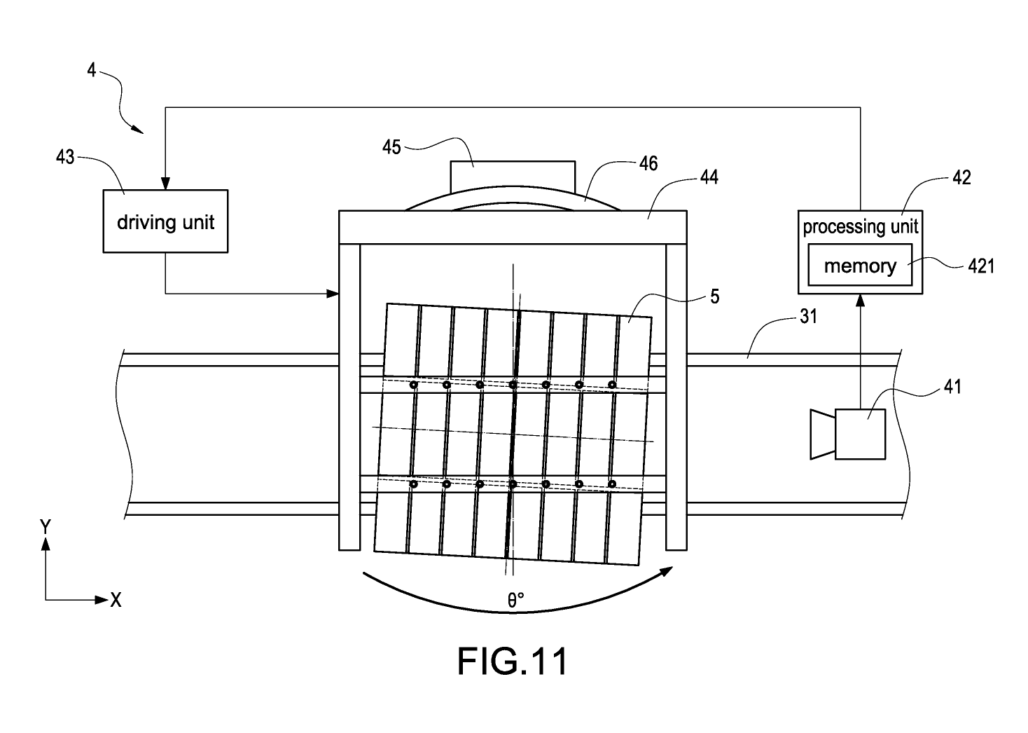

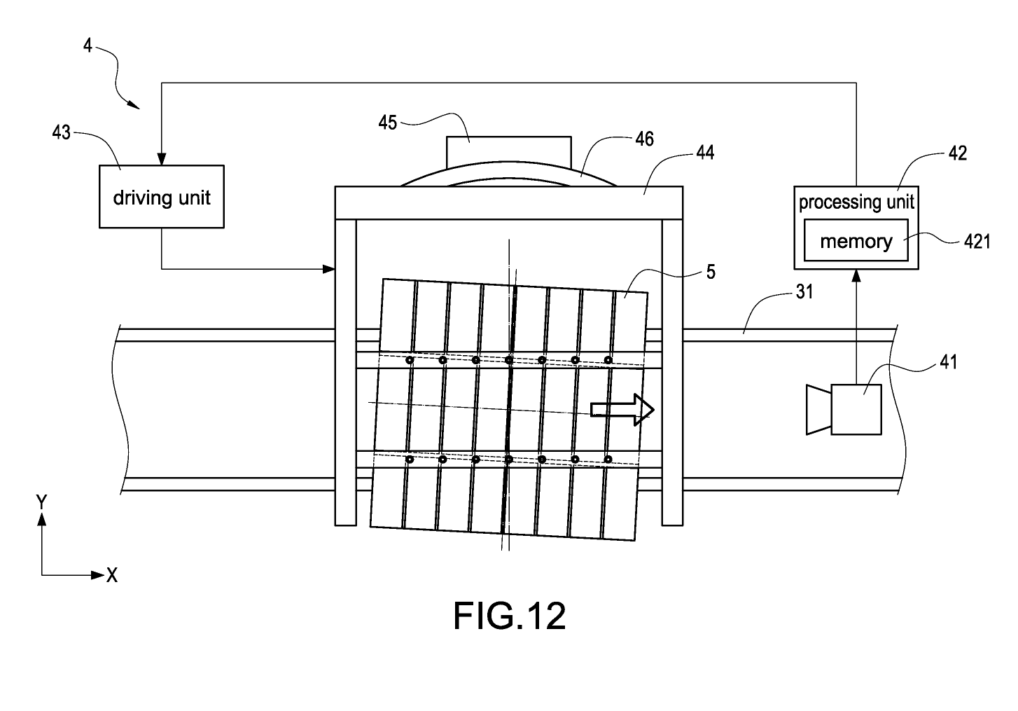

Next, the solar simulator (not shown) in the inspecting apparatus 4 generates simulated sunlight to illuminate vertically a sunlight-receiving surface of the battery panel 5, so that the battery panel 5 can generate electricity by means of the illumination (step S60). As a result, by contacting the probes 441 of the probe devices 44, the voltage and current generated by the battery panel 5 can be outputted, whereby the inspecting apparatus 4 can measure the voltage efficiency and current efficiency generated by the battery panel 5 (step S62). After finishing the measuring step S62, as shown in FIG. 10, the probes 441 move away from the surface of the battery panel 5, and the probe devices 44 finish the pressing action (step S64). Further, after the probe devices 44 finish the pressing action, as shown in FIG. 11, the inspecting apparatus 4 cancels the correction for the offset data so as to make the probe devices 44 to return to their original positions (step S66). Finally, as shown in FIG. 12, the transport platen 31 transports the battery panel 5 that is inspected completely to leave the inspecting apparatus 4 (step S68) for the subsequent process. At the same time, the next solar battery panel is transported to the inspecting apparatus 4 for inspection.

Although the present invention has been described with reference to the foregoing preferred embodiment, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A location-adjusting inspecting apparatus for solar battery panel inspecting system, provided in an inspecting region of the inspecting system for inspecting a solar battery panel transported from a transport platen, the inspecting apparatus including:
an image-fetching device provided on one side of the inspecting region, the image-fetching device being movable toward the inspecting region along a transporting path of the transport platen to fetch an image of electrode lines on the solar battery panel;
a processing unit electrically connected to the image-fetching device, the processing unit being provided therein with a memory for storing a correct data representing the position and angle of the electrode lines, the processing unit configured to compare the data with the image fetched by the image-fetching device to generate an offset data; and
a set of rotatable probe devices provided above and under the solar battery panel to generate a corrective rotation based on the offset data, thereby pressing and contacting the solar battery panel for inspection.

2. The location-adjusting inspecting apparatus for solar battery panel inspecting system according to claim 1, further including a driving unit electrically connected to the processing unit and the probe devices, the driving unit receiving the offset data to drive the probe devices to generate the corrective rotation and press the battery panel for inspection.

3. The location-adjusting inspecting apparatus for solar battery panel inspecting system according to claim 2, wherein the driving unit drives the probe devices by means of a motor screw, a motor cam or a cylinder.

4. The location-adjusting inspecting apparatus for solar battery panel inspecting system according to claim 3, wherein the probe devices are driven by the driving unit to generate the corrective rotation in a horizontal direction, thereby making a plurality of probes on the probe devices to correspond to the position and angle of the electrode lines.

5. The location-adjusting inspecting apparatus for solar battery panel inspecting system according to claim 3, wherein the probe devices are driven by the driving unit to press in a vertical direction to make the probes on the probe devices to contact the electrode lines on upper and lower surfaces of the solar battery panel, thereby generating an electrical conduction to output a voltage and current of the solar battery panel.

6. The location-adjusting inspecting apparatus for solar battery panel inspecting system according to claim 1, wherein the image-fetching device is provided on one side of the probe device above the solar battery panel, and it fetches images toward the inspecting region along the transporting path of the transport platen.

7. A location-adjusting inspecting method used in a location-adjusting inspecting apparatus for a solar battery panel inspecting system, the inspecting apparatus being provided in an inspecting region of the inspecting system, a transport platen of the inspecting system transporting a solar battery panel to the inspecting apparatus for inspection, the method including steps of:
a) fetching an image of electrode lines on the solar battery panel by means of an image-fetching device of the inspecting apparatus;
b) generating an offset data based on the fetched image;
c) controlling a rotatable probe device to generate a corrective rotation based on the offset data; and
d) the probe device contacting the electrode lines after the step c), thereby generating an electrical conduction to output a voltage and current of the solar battery panel.

8. The location-adjusting inspecting method according to claim 7, further including a step e) of cancelling the corrective rotation of the probe device and returning to an original position after the step d).

9. The location-adjusting inspecting method according to claim 8, wherein the fetched image is transmitted to a processing unit in the step b), the fetched image is compared with a correct data stored in a memory of the processing unit representing the poison and angle of the electrode lines, thereby generating the offset data.

10. The location-adjusting inspecting method according to claim 9, wherein the image-fetching device is provided on one side of the inspecting region, and it fetches images toward the inspecting region along the transporting path of the transport platen.

11. The location-adjusting inspecting method according to claim 9, wherein a driving unit of the inspecting apparatus receives the offset data in the step c) to drive the probe devices to generate a corrective rotation in the horizontal direction, thereby making the probes of the probe devices to correspond to the position and angle of the electrode lines.

12. The location-adjusting inspecting method according to claim 11, wherein the probe devices are provided above and under the solar battery panel, the driving unit drives the probe devices to press vertically in the step d) so as to make the probes to contact the electrode lines on upper and lower surfaces of the solar battery panel.

13. The location-adjusting inspecting method according to claim 12, wherein the pressing of the probe devices is non-synchronous, the rotatable probe device above the solar battery panel presses downwards first, and then the rotatable probe device under the inspecting apparatus presses upwards.
